(19) United States
(12) Patent Application Publication
(10) Pub. No.: US 2026/0287650 A1
(43) Pub. Date: Sep. 24, 2026

(54) PROBE HEAD FOR TESTING SEMICONDUCTOR DEVICES

(71) Applicant: TSE CO., LTD., Cheonan-si, Chungcheongnam-do (KR)

(72) Inventors: Young Hun JU, Cheonan-si (KR); Yoon Young JIN, Cheonan-si (KR); Sin Jae KIM, Cheonan-si (KR)

(73) Assignee: TSE CO., LTD., Cheonan-si, Chungcheongnam-do (KR)

(21) Appl. No.: 19/479,827

(22) PCT Filed: Apr. 22, 2024
(86) PCT No.: PCT/KR2024/005417

§ 371 Date: Oct. 29, 2025

(30) Foreign Application Priority Data
May 2, 2023 (KR) 10-2023-0057000
Mar. 22, 2024 (KR) 10-2024-0039917

(51) Int. Cl. G01R 31/28; G01R 1/067

(52) U.S. Cl. CPC G01R 31/2886; G01R 1/06733; G01R 1/06761

(57) ABSTRACT

Disclosed is a probe head for testing semiconductor devices, the probe head including an upper guide plate having an upper receiving hole formed therein, a lower guide plate formed spaced apart from the upper guide plate, the lower guide plate having a lower receiving hole formed therein, and a probe coupled to the upper guide plate and the lower guide plate such that an upper part and a lower part are received in the upper receiving hole and the lower receiving hole, respectively, and a body is located between the upper guide plate and the lower guide plate, wherein the upper part of the probe has a displacement portion formed by displacement of a central axis of the probe along a Z-axis, and the displacement portion generates side reaction force on the upper guide plate.

### CROSS REFERENCE TO RELATED APPLICATIONS

This application is a National Stage of International Application No. PCT/KR 2024/005417 filed on Apr. 22, 2024, claiming priority based on Korean Patent Application Nos. 10-2023-0057000 and 10-2024-0039917 filed on May 2, 2023 and Mar. 22, 2024, respectively.

### TECHNICAL FIELD

The present invention relates to a probe head for testing semiconductor devices, and more particularly to a probe head for testing semiconductor devices configured such that the shape of an upper part of a probe is changed to generate side reaction force such that the probe has binding force in a Z-axis direction.

### Background Art

In general, a process of manufacturing a semiconductor apparatus includes a patterning process of manufacturing semiconductor devices, an electrical die sorting (EDS) process of electrically testing the semiconductor devices to determine whether the semiconductor devices are defective, and an assembly process of integrating each semiconductor device on a wafer.

In the EDS process, which is a process of supplying a test current to each semiconductor device and testing an electrical signal output from the semiconductor device to determine whether the semiconductor device is defective, a probe apparatus that allows a probe to be in electrical contact with each semiconductor device to test the performance of the semiconductor device is widely used.

The probe apparatus includes a tester configured to supply a test current and to test and analyze a signal based thereon, a probe card configured to electrically connect an object to be tested (semiconductor device) and the tester to each other, and a probe configured to be in direct contact with the object to be tested and a printed circuit board of the probe card.

The probe is typically provided in a probe head structure in which a plurality of probes is received and assembled in order to ensure stable contact with the object to be tested and the probe card while maintaining an appropriate contact pressure and to ensure durability for multiple tests.

Generally, the probe head includes a probe and a block in which the probe is received and assembled, wherein a first end and a second end of the probe protrude outward from a first surface and a second surface of the block, respectively, so as to be in electrical contact with the printed circuit board and a contact terminal of the semiconductor device, respectively, at an appropriate pressure.

The block includes an upper guide plate configured to support an upper part of the probe and a lower guide plate configured to support a lower part of the probe, wherein the upper guide plate and the lower guide plate are spaced apart from each other by a predetermined distance in order to stably support the probe.

In each of the upper guide plate and the lower guide plate, a receiving hole is formed at a pitch interval corresponding to a contact terminal of a semiconductor device to be tested, wherein the probe is received and assembled in the receiving hole, and the probe is slid in the receiving hole by a predetermined pressure during testing.

Since the probe is slid in the receiving hole in contact with the printed circuit board and the contact terminal of the semiconductor device, as described above, binding force of the probe in a Z-axis direction is insufficient. In particular, the binding force of the probe in the Z-axis direction is nonuniform due to manufacturing tolerances of the probe or process deviations of the receiving hole, whereby contact stability and accuracy of the probe are reduced.

In addition, such a conventional probe and guide plate assembly structure is unfavorable for maintaining uniform characteristics of a plurality of probes due to the limitations of fine adjustment caused by process and assembly tolerances, and a gap is formed between the respective probes by the weight of the probe due to the lack of binding force in the Z-axis direction, which reduces contact stability, whereby characteristics between the probes become more nonuniform.

In a conventional technique for binding the probe, an offset is provided between the upper guide plate and the lower guide plate to adjust the contact position between the probe and the guide plate such that the probe has reaction force. However, this method is mainly used to bind the probe in an X-axis direction and a Y-axis direction (horizontal direction), and therefore contact stability and accuracy of the probe are lowered, as described above, which is likely to cause measurement errors when precise measurement is required.

### DISCLOSURE

### Technical Problem

The present invention has been made in view of the above problems, and it is an object of the present invention to provide a probe head for testing semiconductor devices configured such that the shape of an upper part of a probe is changed to adjust the distance between the probe and an upper guide plate in order to increase side reaction force, whereby the probe has binding force in a Z-axis direction.

### Technical Solution

In order to accomplish the above object, a probe head for testing semiconductor devices according to the present invention includes an upper guide plate having an upper receiving hole formed therein, a lower guide plate formed spaced apart from the upper guide plate, the lower guide plate having a lower receiving hole formed therein, and a probe coupled to the upper guide plate and the lower guide plate such that an upper part and a lower part are received in the upper receiving hole and the lower receiving hole, respectively, and a body is located between the upper guide plate and the lower guide plate, wherein the upper part of the probe has a displacement portion formed by displacement of a central axis of the probe along a Z-axis, and the displacement portion generates side reaction force on the upper guide plate.

The displacement portion may be formed in a curved shape or a straight shape. In addition, the displacement portion may be formed in a curved shape having at least one inflection point.

The displacement portion may be formed adjacent to a side wall of the upper receiving hole, and the displacement portion may have a displacement amount of 5 to 100 um with respect to a vertical central axis of the probe.

The displacement portion may have a deformation portion configured to control the side reaction force.

The upper part of the probe may be formed in a porous structure.

The upper part of the probe may be formed in a single-slot structure or a multi-slot structure or may have at least one bridge formed between the slots. In addition, the upper part of the probe may be formed in the multi-slot structure, and at least one of the slots may include at least one curved portion, or the upper part of the probe may include one or more slots having different radii of curvature at the curved portion.

The upper part of the probe may be formed in the multi-slot structure, and each slot may include at least one projecting recess. Alternatively, the upper part of the probe may be formed in the multi-slot structure, and one or more of the slots may have different widths.

The upper part of the probe may include at least one protrusion.

The upper part of the probe may be provided with at least one bent portion.

The upper part of the probe may be made of different materials, and an outer layer of the upper part of the probe may be made of a material having higher strength than the material of an inner layer of the upper part of the probe. Alternatively, the upper part of the probe may be made of different materials, and each of an upper end and a lower end of the upper part of the probe may be made of a material having higher strength than the material of a middle region of the upper part of the probe.

### Advantageous Effects

As is apparent from the above description, the shape of an upper part of a probe is changed to adjust the distance between the probe and an upper guide plate in order to increase side reaction force, whereby the probe has binding force in a Z-axis direction, and therefore contact stability, accuracy, and uniformity of the probe are improved.

That is, in the probe according to the present invention, side reaction force is not generated on the probe by a conventional external action (offset of the guide plate) but is generated by the probe, which may induce a difference in displacement of the guide plate in the Z-axis direction. Also, in the present invention, a deformation portion (shape deformation, porous structure, slot structure, or material change) is formed at the upper part of the probe coupled to the upper guide plate to increase the degree of design freedom of a displacement portion such that process and assembly tolerances occurring in a probe and plate assembly structure are alleviated, thereby maintaining uniform characteristics between a plurality of probes.

### DESCRIPTION OF DRAWINGS

FIGS. 1A and 1B are schematic views showing an upper part of a probe according to an embodiment of the present invention and a schematic view showing coupling between the probe and an upper guide plate;

FIGS. 2 to 6C are schematic views showing upper parts of probes according to other embodiments of the present invention; and

FIGS. 7A, 7B, 7C and 7D are views showing a change in the shape of the probe according to the embodiment of the present invention through simulation.

### BEST MODE

The present invention relates to a probe head for testing semiconductor devices, wherein the shape of an upper part of a probe is changed to adjust the distance between the probe and an upper guide plate in order to increase side reaction force, whereby the probe has binding force in a Z-axis direction, and therefore contact stability, accuracy, and uniformity of the probe are improved.

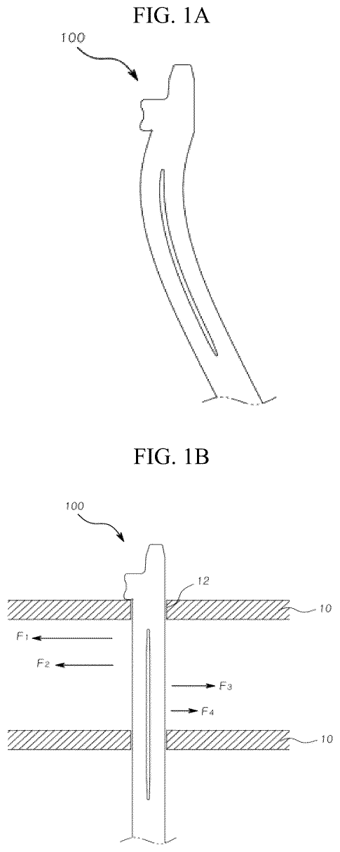

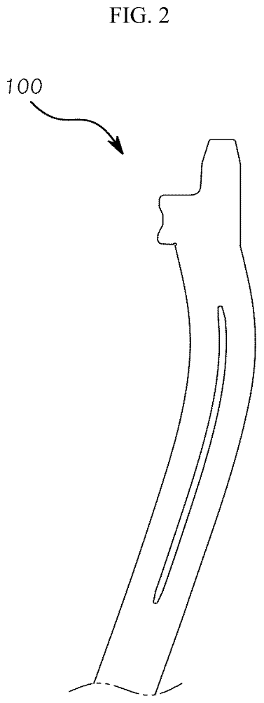

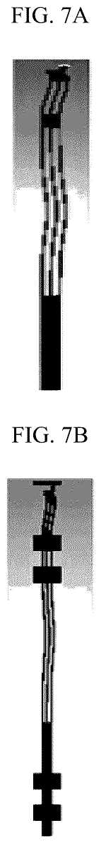

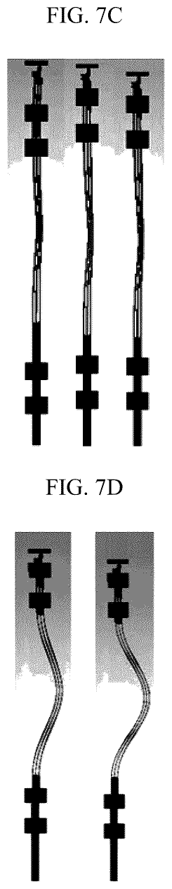

That is, in the probe according to the present invention, side reaction force is not generated on the probe by a conventional external action (offset of the guide plate) but is generated by the probe, which may induce a difference in displacement of the guide plate in the Z-axis direction. Hereinafter, embodiments of the present invention will be described in detail with reference to the accompanying drawings. FIGS. 1A and 1B are schematic views showing an upper part of a probe according to an embodiment of the present invention and a schematic view showing coupling between the probe and an upper guide plate, FIGS. 2 to 6C are schematic views showing upper parts of probes according to other embodiments of the present invention, and FIGS. 7A, 7B, 7C and 7D are views showing a change in the shape of the probe according to the embodiment of the present invention through simulation.

As shown, a probe head for testing semiconductor devices according to an embodiment of the present invention includes an upper guide plate 10 having an upper receiving hole 12 formed therein, a lower guide plate (not shown) formed spaced apart from the upper guide plate 10, the lower guide plate having a lower receiving hole formed therein, and a probe 100 coupled to the upper guide plate 10 and the lower guide plate such that an upper part and a lower part are received in the upper receiving hole 12 and the lower receiving hole, respectively, and a body is located between the upper guide plate 10 and the lower guide plate, wherein the upper part of the probe 100 has a displacement portion formed by displacement of the central axis of the probe along the Z-axis, and the displacement portion generates side reaction force on the upper guide plate 10.

In general, a probe head for testing semiconductor devices includes an upper guide plate 10 and a lower guide plate configured to receive a probe 100 so as to be coupled thereto and to guide the probe 100.

In addition, thousands to tens of thousands of probes 100 are coupled to respective receiving holes (upper receiving holes and lower receiving holes) of the upper guide plate and the lower guide plate to perform the test.

For convenience, the present invention will be described with reference to one probe 100 coupled to the upper guide plate 10 and the lower guide plate, and in particular, the invention relates to features in assembly between the upper receiving hole 12 of the upper guide plate 10 and the probe 100.

A probe head according to an embodiment of the present invention includes an upper guide plate 10 having an upper receiving hole 12 formed therein, a lower guide plate formed spaced apart from the upper guide plate 10, the lower guide plate having a lower receiving hole formed therein, and a probe 100 coupled to the upper guide plate 10 and the lower guide plate such that an upper part and a lower part are received in the upper receiving hole 12 and the lower receiving hole, respectively, and a body is located between the upper guide plate 10 and the lower guide plate.

The probe 100 may be made of an elastic metal or an elastic metal composite material, is constituted by a needle-type pin having an upper tip protruding upward from the upper guide plate 10 and a lower tip protruding downward from the lower guide plate, and is deformed between the upper guide plate 10 and the lower guide plate so as to be in stable contact with a printed circuit board and a contact terminal of an object to be tested.

Here, the upper guide plate 10 may be formed in single or plural in the Z-axis direction, and the upper part of the probe is received in the upper receiving hole 12 formed in each upper guide plate 10.

In a conventional probe and plate assembly structure, as the probe is buckled due to assembly tolerances between the probe and the plate or due to contact pressure between a printed circuit board and an object to be tested, binding force of the probe in the Z-axis direction is insufficient, whereby the probe floats in the receiving hole of the plate, resulting in a decrease in contact stability, accuracy, and uniformity of the probe. In addition, contact between a plurality of probes is nonuniform, resulting in a decrease in accuracy or precision of the test.

The present invention is characterized in that the shape of the upper part of the probe is changed and the upper part of the probe has a displacement portion formed by displacement of the central axis of the probe 100 along the Z-axis. As a result, side reaction force is generated on the upper guide plate 10 by the upper part of the probe, whereby the probe 100 has binding force in the Z-axis direction.

In the probe 100 according to the present invention, side reaction force is not generated on the probe by a conventional external action (offset of the guide plate) but is generated (on the upper guide plate 10) by the probe 100, which may induce a difference in displacement of the guide plate in the Z-axis direction depending on the distance between the probe 100 (the upper part of the probe) and the guide plate.

That is, horizontal load is applied to the upper guide plate 10 by the displacement portion formed by displacement of the central axis of the probe 100 along the Z-axis, and therefore horizontal reaction force (side reaction force) is generated. The side reaction force may be controlled depending on the material, shape, and structure of the upper part of the probe, and the force received by the upper part of the probe due to the side reaction force is transmitted to the entirety of the probe 100.

In particular, the side reaction force may be controlled by changing the shape or material of the probe 100, i.e., by forming a deformation portion (shape deformation, porous structure, slot structure, material change, etc.) configured to control the side reaction force at the upper part of the probe 100, whereby the degree of elastic deformation induced in the upper guide plate 10 may be adjusted, and therefore force may be mutually and organically transmitted to the body of the probe.

Here, the force transmitted to the body of the probe induces the transfer of the reaction force to the upper part of the probe, whereby it is possible to increase the average reaction force of the probe 100, to promote uniformity of the binding force of the probe 100 in the Z-axis direction, and to improve uniformity of the characteristics between the probes.

In the present invention, the displacement portion is formed at the upper part of the probe so as to interact with the side wall of the upper receiving hole 12 of the upper guide plate 10, and is formed by displacement of the central axis of the probe 100 along the Z-axis.

As shown in FIG. 1A, a displacement portion according to an embodiment of the present invention is formed at the upper part of the probe, and is formed by displacement of the central axis of the probe 100 to the left along the Z-axis. FIG. 1B shows a state in which the probe 100 having the displacement portion according to the embodiment of the present invention is received in and coupled to the upper guide plate 10, showing that side reaction forces F1, F2, F3, and F4 are generated on the upper guide plate 10 by the displacement portion formed at the upper part of the probe. In the present embodiment, the magnitude of the side reaction force F1 acting on the upper guide plate 10 at the point where the curvature of the displacement portion is smallest is the largest, and the magnitudes of the side reaction forces F2, F3, and F4 acting on the upper guide plate 10 at the point where the curvature of the displacement portion is relatively large may be small.

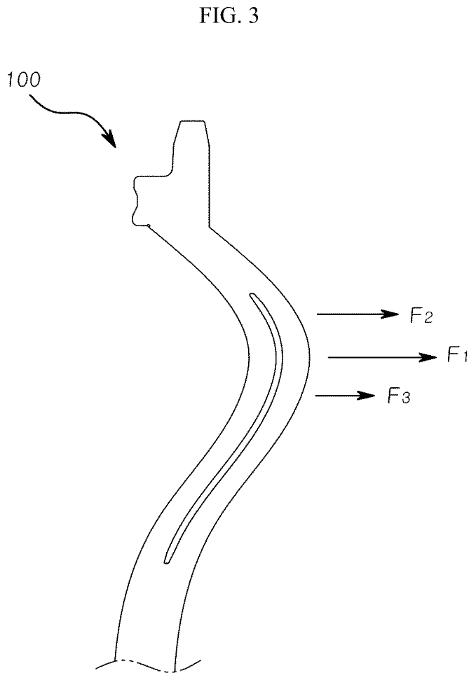

FIG. 2 shows another embodiment of the present invention, wherein a displacement portion is formed by displacement of the central axis of the probe 100 to the right along the Z-axis, and FIG. 3 shows that a displacement portion is formed by further displacement of the central axis of the probe 100 to the right along the Z-axis than in the embodiment of FIG. 2. In the embodiment of FIG. 3, it is expected that the magnitude of the side reaction force F1 at the most highly convex point to the right of the curved surface is the largest.

In the embodiments of FIGS. 1A to 3, the displacement portion is formed in the shape of a single curved surface, and the displacement portion may be formed in the shape of two or more different curved surfaces as needed. That is, the displacement portion may have two or more displacement directions, and the displacement portion may have one or more inflection points, as needed. For example, the displacement portion may have a U-shape or an S-shape, which is a curved shape, or a Z-shape, a W-shape, or a V-shape, which is a straight shape.

In addition, the displacement portion according to the embodiment of the present invention preferably has a displacement amount of 5 to 100 μm with respect to the vertical central axis of the probe 100. If the displacement amount is greater than the above range, the probe 100 may be excessively deformed and the friction force between the probe 100 and the plate may increase, resulting in excessive binding force of the probe 100, which may hinder stable contact, or durability may be reduced by wear of the plate or the probe 100. If the displacement amount is less than the above range, the magnitude of the side reaction force is relatively small, which affects stable binding force of the probe 100 in the Z-axis direction.

Here, the displacement portion is formed adjacent to the side wall of the upper receiving hole 12, and the diameter of the upper receiving hole 12 and the width of the probe 100, i.e., the distance between the side wall of the upper receiving hole 12 and a side wall of the upper part of the probe 100, is comprehensively set in consideration of the magnitude of the displacement amount of the displacement portion, the direction of displacement, the magnitude of the reaction force transmitted to the probe 100 due to the side reaction force acting on the upper guide plate 10, and the like.

As such, the displacement portion according to the present invention may be designed in various shapes depending on the magnitude of the side reaction force acting on the upper guide plate 10 while considering the distance between the side wall of the upper receiving hole 12 and the side wall of the upper part of the probe.

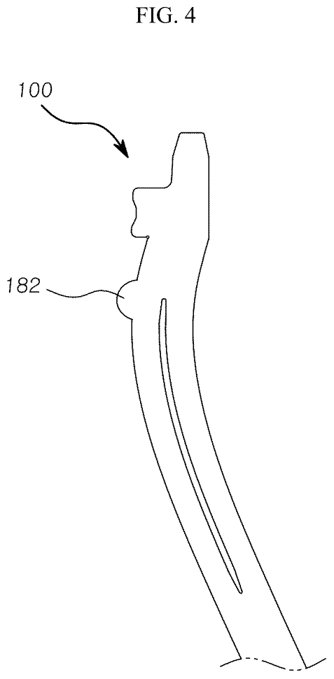

Meanwhile, the displacement portion according to the present invention may have various deformation portions configured to control the side reaction force, which are shown in FIGS. 4 to 6C. The deformation portions are not limited to the above embodiments, and may be formed in any shape, structure, or material such that the deformation portions are elastically deformed by the organic action of horizontal load and side reaction force between the displacement portion and the upper guide plate 10 to control the side reaction force. As shown, a deformation portion of an upper part of a probe according to an embodiment of the present invention may include at least one protrusion 182 formed so as to protrude from the side wall of the upper part of the probe, or may be formed so as to have a porous structure 161. In addition, at least one slot 162 may be formed in the upper part of the probe.

The load and the side reaction force caused by the offset between the upper part of the probe and the upper guide plate 10 are affected by the porous structure 161 and the protrusion 182 of the upper part of the probe, and therefore it is possible to provide a reference for setting an appropriate designable displacement portion (the magnitude of displacement and the direction of displacement) without excessive load being applied to the probe 100.

That is, this affects the side reaction force between the probe 100 and the plate, which causes deformation of the entirety of the probe 100 or the body of the probe, which causes interaction that transfers the side reaction force to the upper part of the probe, whereby it is possible to increase the average reaction force between the probes 100, and therefore it is possible to further promote uniformity of characteristics between the probes 100.

In addition, this structure of the probe 100 may adjust the displacement range of the displacement portion of the probe 100 and the distance from the side wall of the upper receiving hole 12 of the upper guide plate 10 through the interaction and transition between the average reaction force and the side reaction force, whereby it is possible to mitigate process deviations and assembly deviations, which further contributes to maintaining uniform characteristics between the probes 100.

FIG. 4 shows an example of the deformation portion, wherein the deformation portion includes at least one protrusion 182 formed on the upper part of the probe. As shown, the protrusion 182 is preferably formed at the maximum displacement point of the displacement portion; however, the present invention is not limited thereto, and a plurality of protrusions 182 of various sizes and shapes may be formed on a convex surface of the displacement portion.

This mitigates process deviations and assembly deviations and promotes uniformity of characteristics between the probes 100 depending on the interaction between the average reaction force and the side reaction force, as described above. The shape and number of the slots 162, the protrusions 182, and bent portions may be set in various combinations, and may be determined depending on the overall shape of the probe 100 and the shape of the displacement portion.

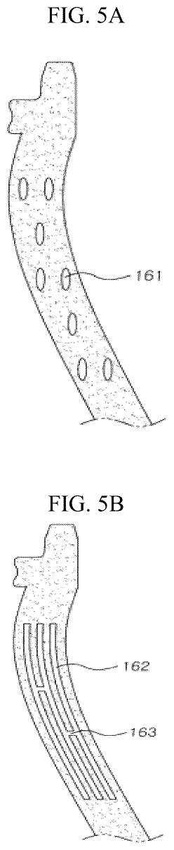

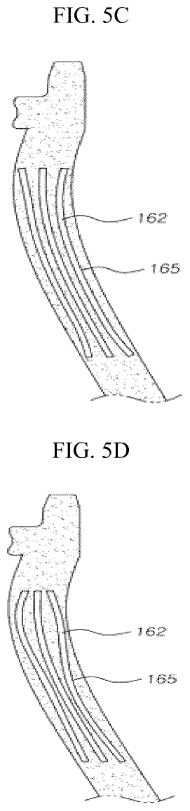

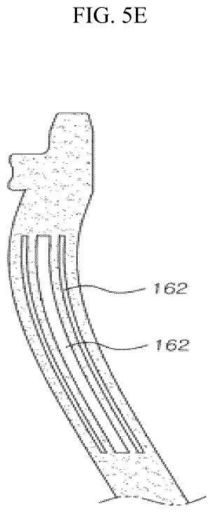

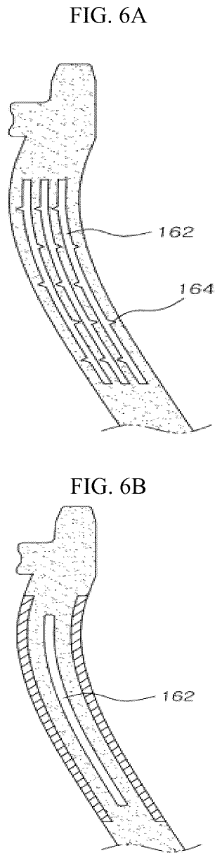

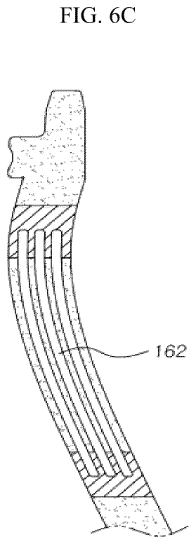

FIGS. 5A to 6C show various embodiments of the deformation portion formed on the upper part of the probe, wherein FIG. 5A shows that the deformation portion has a circular porous Structure 161, FIG. 5B shows that the deformation portion has a plurality of slots 162 and at least one bridge 163 connecting the slots 162 to each other, FIGS. 5C and 5D show that the deformation portion has a multi-slot structure including a plurality of slots 162, in which at least one of the slots 162 includes one or more curved portions 165 having the same radius of curvature or different radii of curvature, and FIG. 5E show that the deformation portion has a multi-slot structure including a plurality of slots 162, in which one or more of the slots 162 have different widths.

As such, the deformation portion, such as the porous structure 161, the slot structure, and the protrusion 182, is formed at the upper part of the probe, i.e., in the region where the side reaction force is generated between the probe 100 and the upper guide plate 10, whereby it is possible to distribute the reaction force (stress or the like) acting on the probe 100, to adjust the average reaction force at the probe 100, and to cause interaction between the side reaction forces, and therefore it is possible to further stabilize the binding force of the probe 100 in the Z-axis direction.

In particular, the multi-slot structure having the curved portion 165 distributes the horizontal load and the side reaction force along the displacement portion as a whole and adjusts the degree of deformation of the body of the probe, whereby it is possible to the designable shape of the displacement portion, and therefore it is possible to alleviate tolerances due to process and assembly deviations. In the embodiment of FIG. 5C, the slot 162 provided at the outside of the upper part of the probe is concavely formed so as to have a large radius of curvature to provide greater (bending) strength to the outside of the upper part of the probe, whereby it is possible to further stabilize or increase the distribution of horizontal load and the side reaction force applied to the probe 100 in the multi-slot structure. In FIG. 5D, the distribution of horizontal load and the side reaction force is more uniformly applied to the upper guide plate 10. In FIG. 5E, the slot 162 provided at the outside of the upper part of the probe is formed so as to have a narrower width to increase bending strength on the outside of the upper part of the probe, whereby it is possible to increase and further stabilize the distribution of the horizontal load and the side reaction force in the multi-slot structure.

FIG. 6A shows that the upper part of the probe has a multi-slot structure, in which at least one projecting recess 164 is formed at each slot 162, and FIGS. 6B and 6C show that the upper part of the probe has a multi-slot structure and is made of different materials. In FIG. 6B, an inner layer and an outer layer of the upper part of the probe are made of different materials, and the strength of the material of the outer layer is higher the strength of the material of the inner layer as an embodiment. In FIG. 6C, an upper end and a lower end of the upper part of the probe are made of different materials, and the strength of the material of each of the upper end and the lower end of the upper part of the probe is higher the strength of the material of a middle region of the upper part of the probe as an embodiment.

The structure of the upper part of the probe of FIGS. 6A, 6B and 6C is configured such that the usable range of the displacement portion can be adjusted by adjusting the horizontal load acting on the body of the probe and the side reaction force acting on the upper guide plate 10 to induce deformation of the body of the probe that causes the side reaction force to be generated by the probe 100, thereby alleviating tolerances due to process and assembly deviations.

In the structure of each of FIGS. 6B and 6C, bending strength on the outside of the upper part of the probe 100 is further increased, or bending strength on the upper end or the lower end of the upper part of the probe is further increased, whereby it is possible to increase and further stabilize the side reaction force.

As such, the deformation portion is formed at the upper part of the probe, i.e., in the region where the horizontal load and the side reaction force act, to generate the side reaction force on the upper guide plate 10, and reaction force resulting therefrom is transmitted to the body of the probe, whereby it is possible to set the designable shape of the displacement portion, and the average reaction force of the probe 100 may be increased, whereby it is possible to alleviate design and process tolerances and to improve uniformity of characteristics between the probes 100.

To this end, in an embodiment of the present invention, various combinations between deformation portions, such as the porous structure 161, the protruding structure, the slot structure, and the deformation portion made of different materials, may be implemented.

Hereinafter, Various Experimental Examples Using the embodiment of the present invention will be described.

The displacement portion had a shape convex to the right, and the displacement amount of the displacement portion (the degree of displacement of the displacement portion from the central axis in the X-axis or Y-axis direction) was set to 5 μm, 10 μm, 15 μm, and 20 μm.

It can be seen that side reaction force was generated on the upper guide plate 10, and therefore reaction force resulting therefrom, i.e., stress, was distributed on the upper part of the probe. It can be seen that the displacement amount of the displacement portion is proportional to the stress.

When the displacement amount was 5 μm, almost no stress was generated, and for a displacement amount of 20 μm, a maximum allowable stress of 320 MPa was observed. This is ⅓ of the safe stress range allowed by the material of the probe, which is the range in which the condition of the applied displacement amount does not cause plastic deformation of the probe, and it is preferable to design the displacement portion within a range of 5 to 100 μm about the vertical central axis of the probe. When the displacement amount was greater than 20 μm, the probe is damaged, or the plate is excessively worn. More preferably, the displacement amount is 10 to 50 μm, and adjustment of the displacement amount may allow for greater freedom in design values by implementing the deformation portion in the shape and material of the upper part of the probe for optimal control of the side reaction force.

FIGS. 7A, 7B, 7C and 7D are views showing a change in the shape of the probe according to the embodiment of the present invention through simulation during testing using the probe, specifically a change in the shape of a probe of a probe head including an upper guide plate having an upper receiving hole formed therein, a lower guide plate formed spaced apart from the upper guide plate, the lower guide plate having a lower receiving hole formed therein, and a probe coupled to the upper guide plate and the lower guide plate such that an upper part and a lower part are received in the upper receiving hole and the lower receiving hole, respectively, and a body is located between the upper guide plate and the lower guide plate.

FIG. 7A schematically shows the overall shape of the probe used in the present simulation, wherein the displacement portion has the shape of a curved surface convex to the right, and the maximum displacement amount of the displacement portion was set to 20 μm.

FIG. 7B shows the state in which the probe of FIG. 7A is coupled to the upper guide plate and the lower guide plate, and FIG. 7C shows a change in the shape of the probe coupled in the guide plate as force is gradually applied downward from the head of the probe in FIG. 7B. It can be seen that the body of the probe is bent to the right as the force is applied in a direction toward the head of the probe.

FIG. 7D shows the state in which the force is finally applied, and it can be seen that the body of the probe and the parts of the probe adjacent to the upper guide plate and the lower guide plate have changed colors from blue to light green and orange, which may be regarded as the force in an object that resists external force.

That is, side reaction force is applied to the upper guide plate by the displacement portion according to the invention, which is transmitted to the probe as reaction force, whereby stress is generated in the entirety of the probe, and it can be seen that side reaction force is generated when the probe is operated as the result of changing the shape of the probe even without offsetting the guide plate.

As is apparent from the above description, the shape of an upper part of a probe is changed to adjust the distance between the probe and an upper guide plate in order to increase side reaction force, whereby the probe has binding force in a Z-axis direction, and therefore contact stability, accuracy, and uniformity of the probe are improved.

That is, in the probe according to the present invention, side reaction force is not generated on the probe by a conventional external action (offset of the guide plate) but is generated by the probe, which may induce a difference in displacement of the guide plate in the Z-axis direction.

1. A probe head for testing semiconductor devices, the probe head comprising:
an upper guide plate having an upper receiving hole formed therein;
a lower guide plate formed spaced apart from the upper guide plate, the lower guide plate having a lower receiving hole formed therein; and
a probe coupled to the upper guide plate and the lower guide plate such that an upper part and a lower part are received in the upper receiving hole and the lower receiving hole, respectively, and a body is located between the upper guide plate and the lower guide plate, wherein the upper part of the probe has a displacement portion formed by displacement of a central axis of the probe along a Z-axis, and
the displacement portion generates side reaction force on the upper guide plate.

2. The probe head according to claim 1, wherein the displacement portion is formed in a curved shape or a straight shape.

3. The probe head according to claim 1, wherein the displacement portion is formed in a curved shape having at least one inflection point.

4. The probe head according to claim 1, wherein the displacement portion is formed adjacent to a side wall of the upper receiving hole.

5. The probe head according to claim 1, wherein the displacement portion has a displacement amount of 5 to 100 μm with respect to a vertical central axis of the probe.

6. The probe head according to claim 1, wherein the displacement portion has a deformation portion configured to control the side reaction force.

7. The probe head according to claim 6, wherein the upper part of the probe is formed in a porous structure.

8. The probe head according to claim 6, wherein the upper part of the probe is formed in a single-slot Structure or a multi-slot structure.

9. The probe head according to claim 8, wherein the upper part of the probe has at least one bridge formed between the slots.

10. The probe head according to claim 8, wherein
the upper part of the probe is formed in the multi-slot structure, and
at least one of the slots comprises at least one curved portion.

11. The probe head according to claim 10, wherein the upper part of the probe comprises one or more slots having different radii of curvature at the curved portion.

12. The probe head according to claim 8, wherein
the upper part of the probe is formed in the multi-slot structure, and
each slot comprises at least one projecting recess.

13. The probe head according to claim 8, wherein
the upper part of the probe is formed in the multi-slot structure, and
one or more of the slots have different widths.

14. The probe head according to claim 6, wherein the upper part of the probe comprises at least one protrusion.

15. The probe head according to claim 6, wherein the upper part of the probe is provided with at least one bent portion.

16. The probe head according to claim 6, wherein
the upper part of the probe is made of different materials, and
an outer layer of the upper part of the probe is made of a material having higher strength than a material of an inner layer of the upper part of the probe.

17. The probe head according to claim 6, wherein
the upper part of the probe is made of different materials, and
each of an upper end and a lower end of the upper part of the probe is made of a material having higher strength than a material of a middle region of the upper part of the probe.
